(19) United States
(12) Patent Application Publication
(10) Pub. No.: US 2020/0169273 A1
(43) Pub. Date: May 28, 2020

(54) APPARATUS AND METHOD FOR ESTIMATING BURST ERROR

(71) Applicant: ELECTRONICS AND TELECOMMUNICATIONS RESEARCH INSTITUTE, Daejeon (KR)

(72) Inventors: Sang Rok MOON, Daejeon (KR); Hun Sik KANG, Daejeon (KR)

(21) Appl. No.: 16/553,445

(22) Filed: Aug. 28, 2019

(30) Foreign Application Priority Data
Nov. 22, 2018 (KR) 10-2018-0145164

(51) Int. Cl. H03M 13/17; H04L 1/00; H04B 10/61

(52) U.S. Cl. CPC H03M 13/17; H04B 10/6164; H04L 1/0071

(57) ABSTRACT

A method and apparatus for estimating a burst error. A burst error estimation method includes measuring a frequency of a spectrum null for an optical signal received through an optical receiver; determining whether the measured frequency of the spectrum null corresponds to an intermediate frequency of a baud rate; and estimating that a burst error occurrence condition is met when the frequency of the spectrum null is determined to correspond to the intermediate frequency of the baud rate.

### CROSS-REFERENCE TO RELATED APPLICATION(S)

This application claims the priority benefit of Korean Patent Application No. 10-2018-0145164, filed on Nov. 22, 2018 in the Korean Intellectual Property Office, the disclosure of which is incorporated herein by reference for all purposes.

### BACKGROUND

### 1. Field

One or more example embodiments relate to a method and apparatus for estimating a burst error, and more particularly, to technology for measuring a frequency of a spectrum null for an optical signal received through an optical receiver and estimating a burst error occurrence condition based on a correlation between the measured frequency of the spectrum null and a baud rate.

### 2. Description of Related Art

In an optical communication system that transmits an optical signal through an optical fiber, a distortion may occur in an optical signal output from an optical transmitter and received by an optical receiver due to chromatic dispersion present in the optical fiber. In detail, in the case of an optical signal that is received through a double sideband direct detection scheme used in a general optical communication system, a null occurs in a receive frequency spectrum due to a power fading effect and a specific frequency component may be lost, which may lead to deteriorating a distortion in the optical signal.

A digital signal processing (DSP) apparatus of the optical receiver may perform DSP to compensate for a distortion of an optical signal that occurs during a transmission process after receiving the optical signal.

In detail, the DSP apparatus may generally use a chromatic dispersion compensation scheme, such as a decision feedback equalizer (DFE) and a maximum likelihood sequence estimation (MLSE) to compensate for a distortion of an optical signal. The chromatic dispersion compensation scheme may enhance the performance by applying a signal value of an optical signal received through the optical receiver to compensation of a subsequent optical signal.

However, when the DSP apparatus erroneously determines a signal value of the optical signal received through the optical receiver, the DSP apparatus may apply the to erroneously determined signal value of the optical signal to compensation of a subsequent optical signal, which may increase a probability that the subsequent optical signal is erroneously determined.

The above phenomenon is referred to as an error-propagation. The error-propagation phenomenon may cause a burst error that errors occur at a time in terms of time. The caused burst error may deteriorate an error correction performance of a forward error correction (FEC) apparatus connected at a rear end of the DSP apparatus.

Accordingly, there is a need for a method that may estimate a burst error occurrence condition to avoid a burst error occurrence condition or to prevent an adverse effect from the burst error.

### SUMMARY

At least one example embodiment provides an apparatus and method for estimating a burst error occurring in a digital signal processing (DSP) apparatus of an optical receiver due to power fading.

At least one example embodiments also provides an apparatus and method for measuring a frequency of a spectrum null for an optical signal received through an optical receiver and estimating a burst error occurrence condition based on whether the measured frequency of the spectrum null corresponds to an intermediate frequency of a baud rate.

According to an aspect, there is provided a method of estimating a burst error, the method including measuring a frequency of a spectrum null for an optical signal received through an optical receiver; determining whether the measured frequency of the spectrum null corresponds to an intermediate frequency of a baud rate; and estimating that a burst error occurrence condition is met when the frequency of the spectrum null is determined to correspond to the intermediate frequency of the baud rate.

The burst error estimation method may further include preventing an adverse effect from the burst error when the burst error occurrence condition is estimated to be met.

The preventing may include preventing the adverse effect from the burst error by adjusting a chromatic dispersion compensation value of a tunable dispersion compensator and changing the frequency of the spectrum null of the optical signal received through the optical receiver.

The preventing may include preventing the adverse effect from the burst error by dispersing an optical signal output through an optical transmitter over time using an interleaver.

Activation of the interleaver may be determined based on the burst error occurrence condition.

According to an aspect, there is provided an apparatus for estimating a burst error, the apparatus including a processor configured to estimate a burst error of an optical signal received through an optical receiver. The processor is configured to measure a frequency of a spectrum null for the optical signal received through the optical receiver, to determine whether the measured frequency of the spectrum null corresponds to an intermediate frequency of a baud rate, and to estimate that a burst error occurrence condition is met when the frequency of the spectrum null is determined to correspond to the intermediate frequency of the baud rate.

The processor may be configured to prevent an adverse effect from the burst error when the burst error occurrence condition is estimated to be met.

The processor may be configured to prevent the adverse effect from the burst error by adjusting a chromatic dispersion compensation value of a tunable dispersion compensator and changing the frequency of the spectrum null of the optical signal received through the optical receiver.

The processor may be configured to prevent the adverse effect from the burst error by dispersing an optical signal output through an optical transmitter over time using an interleaver.

Activation of the interleaver may be determined based on the burst error occurrence condition.

According to an aspect, there is provided a method of estimating a burst error, the method including measuring a frequency of a spectrum null by analyzing a frequency component of an optical signal received through an optical receiver; and estimating a burst error occurrence condition for the received optical signal based on a ratio of the measured frequency of the spectrum null to a frequency of a baud rate.

The determining may include determining that the burst error occurrence condition for the received optical signal is met when the ratio of the measured frequency of the spectrum null to the frequency of the baud rate corresponds to 0.5 that is an intermediate ratio.

The burst error estimation method may further include preventing an adverse effect from the burst error when the burst error occurrence condition for the received optical signal is estimated to be met.

The preventing may include preventing the adverse effect from the burst error by adjusting a chromatic dispersion compensation value of a tunable dispersion compensator and changing the frequency of the spectrum null of the optical signal received through the optical receiver.

The preventing may include preventing the adverse effect from the burst error by dispersing an optical signal output through an optical transmitter over time using an interleaver.

Activation of the interleaver may be determined based on the burst error occurrence condition.

According to some example embodiments, it is possible to estimate a burst error occurring in a DSP apparatus of an optical receiver due to power fading.

According to some example embodiments, it is possible to measure a frequency of a spectrum null for an optical signal received through an optical receiver and to estimate a burst error occurrence condition based on whether the measured frequency of the spectrum null corresponds to an intermediate frequency of a baud rate.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a diagram illustrating a burst error estimation apparatus according to an example embodiment;

FIG. 2 is a graph showing a length of a burst error based on a correlation between a frequency of a spectrum null and a baud rate according to an example embodiment;

FIG. 3 illustrates an example of preventing occurrence of a burst error according to an example embodiment;

FIG. 4 illustrates another example of preventing occurrence of a burst error according to an example embodiment; and

FIG. 5 is a flowchart illustrating a burst error estimation method according to an example embodiment.

### DETAILED DESCRIPTION

Hereinafter, some example embodiments will be described in detail with reference to the accompanying drawings. However, various alterations and modifications may be made to the example embodiments. Here, the example embodiments are not construed as limited to the disclosure and should be understood to include all changes, equivalents, and replacements within the idea and the technical scope of the disclosure.

The terminology used herein is for the purpose of describing particular example embodiments only and is not to be limiting of the example embodiments. As used herein, the singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the example embodiments with reference to the accompanying drawings, like reference numerals refer to like constituent elements and a repeated description related thereto will be omitted. In the description of example embodiments, detailed description of well-known related structures or functions will be omitted when it is deemed that such description will cause ambiguous interpretation of the present disclosure.

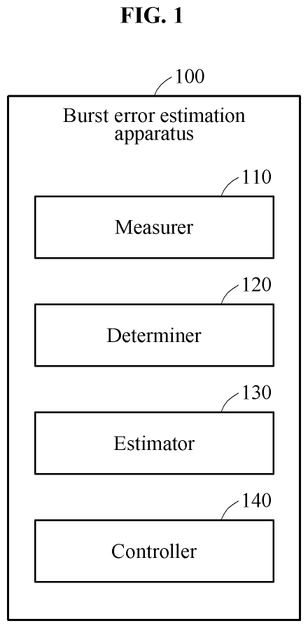

FIG. 1 is a diagram illustrating a burst error estimation apparatus according to an example embodiment.

A burst error estimation apparatus 100 according to an example embodiment may prevent a distortion of an optical signal from occurring due to a burst error by estimating in advance whether a burst error occurrence condition is met by a power fading effect.

Here, a burst error may generally occur in a transmission pattern in which an optical signal repeats “high, low, high, low . . . ” because an error occurring in the transmission pattern of “high, low, high, low . . . ” is easily propagated to a subsequent symbol and becomes the burst error.

Here, energy of the transmission pattern of “high, low, high, low . . . ” is concentrated on an intermediate frequency domain of a baud rate in a frequency domain. Accordingly, when a frequency portion corresponding to the intermediate frequency domain of the baud rate is lost, a probability that an error may occur in the transmission pattern of “high, low, high, low . . . ” increases and, at the same time, a probability (hereinafter, also referred to as a burst error occurrence probability) that a burst error may occur increases.

The burst error estimation apparatus 100 may estimate whether a burst error occurrence condition is met based on the aforementioned condition.

Referring to FIG. 1, the burst error estimation apparatus 100 may include a measurer 110, a determiner 120, an estimator 130, and a controller 140. The measurer 110 may measure a frequency of a spectrum null for an optical signal received through an optical receiver according to the following Equation 1.

$${f}_{null} = \sqrt{\frac{c}{2 D {λ}^{2} L} ( 1 + 2 u - \frac{2}{π} arctan ( α ) )} \qquad [ Equation 1 ]$$

In Equation 1, C denotes a speed of light, D denotes a dispersion parameter, λ denotes an optical wavelength, L denotes a transmission distance, u denotes order of a null, and α denotes a chirp parameter.

The determiner 120 may determine whether the measured frequency of the spectrum null corresponds to an intermediate frequency of a baud rate. As described above, when a frequency portion corresponding to the intermediate frequency domain of the baud rate is lost in a signal spectrum of the received optical signal, a probability that an error may occur in the transmission pattern of “high, low, high, low . . . ” increases and, at the same time, a burst error occurrence probability increases. Accordingly, when the measured frequency of the spectrum null corresponds to the intermediate frequency of the baud rate, it may indicate an increase in the burst error occurrence probability.

Accordingly, when the frequency of the spectrum null is determined to correspond to the intermediate frequency of the baud rate, the estimator 130 may estimate that a burst error occurrence condition is met.

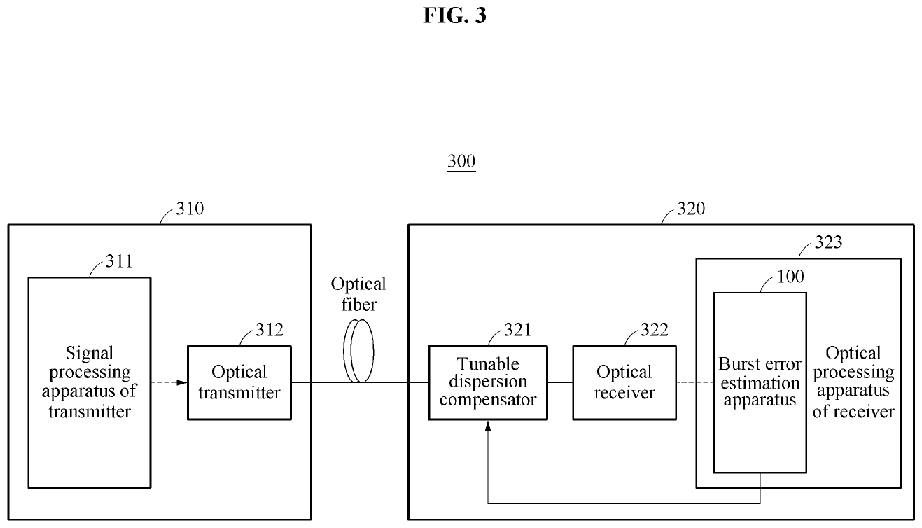

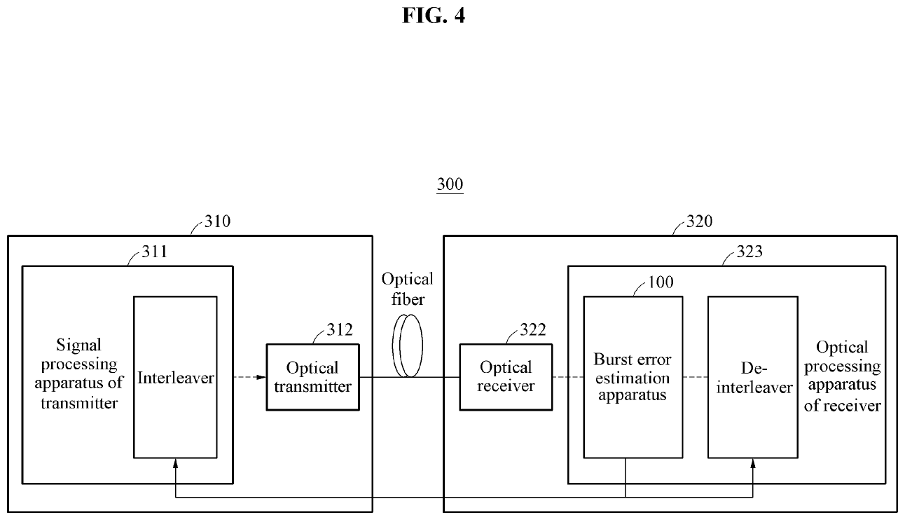

When the estimator 130 estimates that the burst error occurrence condition is met, the controller 140 may control an optical component constituting the optical communication system to prevent the occurrence of the burst error, which may lead to preventing an adverse effect from the burst error. In detail, since the burst error occurrence probability increases when the measured frequency of the spectrum null corresponds to the intermediate frequency of the baud rate, the controller 140 may change the frequency of the spectrum null not to correspond to the intermediate frequency of the baud rate or may disperse an optical signal output from an optical transmitter over time, thereby preventing the adverse effect from the burst error. A method of preventing an adverse effect from a burst error is further described with reference to FIGS. 3 and 4.

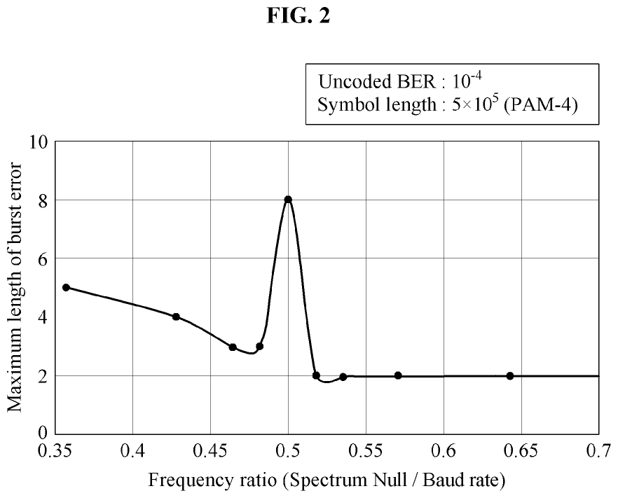

FIG. 2 is a graph showing a length of a burst error based on a correlation between a frequency of a spectrum null and a baud rate according to an example embodiment.

FIG. 2 illustrates a simulation result of calculating a maximum length of a burst error occurring when a specific frequency component is lost in a signal spectrum of a received optical signal. Here, a decision feedback equalizer (DFE) and a maximum likelihood sequence estimation (MLSE) are used for a digital signal processing (DSP) algorithm and a PAM-4 signal is used. A total number of errors in the simulation is maintained to be almost identical with respect to all of the cases.

Referring to FIG. 2, when a ratio of a frequency of a spectrum null to a frequency of a baud rate (Spectrum Null/Baud rate) corresponds to 0.5, it can be verified that a relatively great burst error abruptly occurs.

Accordingly, the burst error estimation apparatus 100 may prevent the occurrence of the burst error by changing the frequency of the spectrum null not to correspond to the intermediate frequency of the baud rate.

FIG. 3 illustrates an example of preventing occurrence of a burst error according to an example embodiment.

A transmitter 310 of an optical communication system 300 may control an optical transmitter 312 through a signal processing apparatus 311 to transmit an optical signal to a receiver 320 through an optical fiber. The receiver 320 may include a tunable dispersion compensator 321 configured to reduce a chromatic dispersion of the received optical signal.

The burst error estimation apparatus 100 may be included in a signal processing apparatus 323 of the receiver 320. When the optical signal is received through an optical receiver 322, whether a burst error occurrence condition is met may be estimated.

Here, when the burst error occurrence condition is estimated to be met, the burst error estimation apparatus 100 may generate a control signal and may adjust a chromatic dispersion compensation value of the tunable dispersion compensator 321.

In detail, as represented by Equation 1, a frequency of a spectrum null may be determined based on a chromatic dispersion amount (D·L) occurring in the optical fiber, a transmission distance, a chirp parameter, and a chromatic dispersion compensation value of the tunable dispersion compensator 321. Accordingly, the burst error estimation apparatus 100 may change the frequency of the spectrum null by changing the chromatic dispersion compensation value of the tunable dispersion compensator 321, which may lead to not meeting the burst error occurrence condition.

FIG. 4 illustrates another example of preventing occurrence of a burst error according to an example embodiment.

A method of preventing, by the burst error estimation apparatus 100, occurrence of a burst error when the transmitter 310 and the receiver 320 are intercommunicable is described with reference to FIG. 4.

When a burst error occurrence condition is estimated to be met, the burst error estimation apparatus 100 may activate an apparatus that is included in the transmitter 310 or the receiver 320 to prevent an adverse effect from a burst error. That is, the apparatus capable of preventing the adverse effect from the burst error may operate only when the burst error occurrence condition is estimated to be met by the burst error estimation apparatus 100.

For example, the apparatus capable of preventing the adverse effect from the burst error may be an interleaver and a de-interleaver. The interleaver may be an apparatus configured to disperse an input signal over time. Therefore, a burst error concentrated in terms of time may be dispersed using the interleaver. The interleaver increases latency of the signal processing apparatus 311. The de-interleaver may realign signals scattered over time by the interleaver.

Therefore, the burst error estimation apparatus 100 may inactivate the interleaver when the burst error occurrence condition is not met, and may activate the interleaver when the burst error occurrence condition is met.

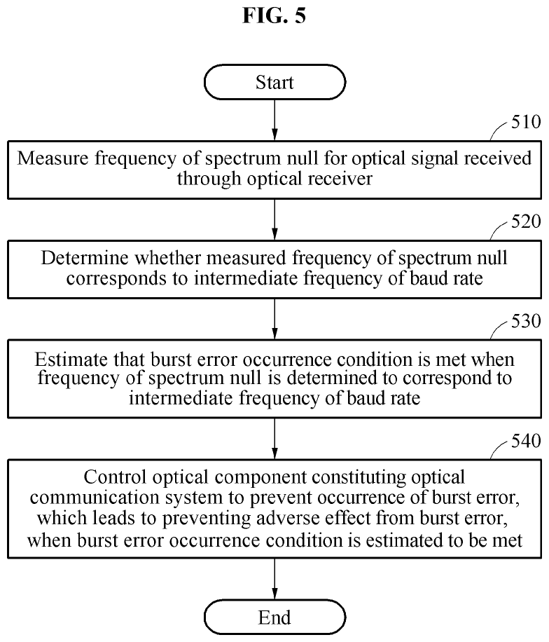

FIG. 5 is a flowchart illustrating a burst error estimation method according to an example embodiment.

Referring to FIG. 5, in operation 510, the burst error estimation apparatus 100 may measure a frequency of a spectrum null for an optical signal received through an optical receiver.

In operation 520, the burst error estimation apparatus 100 may determine whether the measured frequency of the spectrum null corresponds to an intermediate frequency of a baud rate. As described above, when a frequency portion corresponding to an intermediate frequency domain of a baud rate is lost in a signal spectrum of a received optical signal a probability that an error may occur in a transmission pattern of “high, low, high, low . . . ” increases, and, at the same time, a burst error occurrence probability increases. Accordingly, when the measured frequency of the spectrum null corresponds to the intermediate frequency of the baud rate, it may indicate an increase in the burst error occurrence probability.

In operation 530, when the frequency of the spectrum null is determined to correspond to the intermediate frequency of the baud rate, the burst error estimation apparatus 100 may estimate that the burst error occurrence condition is met.

In operation 540, when the burst error occurrence condition is estimated to be met, the burst error estimation apparatus 100 may control an optical component constituting the optical communication system to prevent the occurrence of the burst error, which may lead to preventing an adverse effect from the burst error. Here, to prevent occurrence of the burst error, the burst error estimation apparatus 100 may change the frequency of the spectrum null not to correspond to the intermediate frequency of the baud rate or may disperse an optical signal output from an optical transmitter over time, thereby preventing the adverse effect from the burst error.

To this end, when the burst error occurrence condition is estimated to be met, the burst error estimation apparatus 100 may change the frequency of the spectrum null by generating a control signal and adjusting a chromatic dispersion compensation value of a tunable dispersion compensator.

Alternatively, when the burst error occurrence condition is estimated to be met, the burst error estimation apparatus 100 may prevent the adverse effect from the burst error by dispersing the burst error concentrated in terms of time using an interleaver.

The components described in the example embodiments may be achieved by hardware components including at least one DSP (Digital Signal Processor), a processor, a controller, an ASIC (Application Specific Integrated Circuit), a programmable logic element such as an FPGA (Field Programmable Gate Array), other electronic devices, and combinations thereof. At least some of the functions or the processes described in the example embodiments may be achieved by software, and the software may be recorded on a recording medium. The components, the functions, and the processes described in the example embodiments may be achieved by a combination of hardware and software.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A method of estimating a burst error, the method comprising:
measuring a frequency of a spectrum null for an optical signal received through an optical receiver;
determining whether the measured frequency of the spectrum null corresponds to an intermediate frequency of a baud rate; and
estimating that a burst error occurrence condition is met when the frequency of the spectrum null is determined to correspond to the intermediate frequency of the baud rate.

2. The method of claim 1, further comprising:
preventing an adverse effect from the burst error when the burst error occurrence condition is estimated to be met.

3. The method of claim 2, wherein the preventing comprises preventing the adverse effect from the burst error by adjusting a chromatic dispersion compensation value of a tunable dispersion compensator and changing the frequency of the spectrum null of the optical signal received through the optical receiver.

4. The method of claim 2, wherein the preventing comprises preventing the adverse effect from the burst error by dispersing an optical signal output through an optical transmitter over time using an interleaver.

5. The method of claim 4, wherein activation of the interleaver is determined based on the burst error occurrence condition.

6. An apparatus for estimating a burst error, the apparatus comprising:
a processor configured to estimate a burst error of an optical signal received through an optical receiver,
wherein the processor is configured to measure a frequency of a spectrum null for the optical signal received through the optical receiver, to determine whether the measured frequency of the spectrum null corresponds to an intermediate frequency of a baud rate, and to estimate that a burst error occurrence condition is met when the frequency of the spectrum null is determined to correspond to the intermediate frequency of the baud rate.

7. The apparatus of claim 6, wherein the processor is configured to prevent an adverse effect from the burst error when the burst error occurrence condition is estimated to be met.

8. The apparatus of claim 7, wherein the processor is configured to prevent the adverse effect from the burst error by adjusting a chromatic dispersion compensation value of a tunable dispersion compensator and changing the frequency of the spectrum null of the optical signal received through the optical receiver.

9. The apparatus of claim 7, wherein the processor is configured to prevent the adverse effect from the burst error by dispersing an optical signal output through an optical transmitter over time using an interleaver.

10. The apparatus of claim 9, wherein activation of the interleaver is determined based on the burst error occurrence condition.

11. A method of estimating a burst error, the method comprising:
measuring a frequency of a spectrum null by analyzing a frequency component of an optical signal received through an optical receiver; and
estimating a burst error occurrence condition for the received optical signal based on a ratio of the measured frequency of the spectrum null to a frequency of a baud rate.

12. The method of claim 11, wherein the determining comprises determining that the burst error occurrence condition for the received optical signal is met when the ratio of the measured frequency of the spectrum null to the frequency of the baud rate corresponds to 0.5 that is an intermediate ratio.

13. The method of claim 11, further comprising:
preventing an adverse effect from the burst error when the burst error occurrence condition for the received optical signal is estimated to be met.

14. The method of claim 13, wherein the preventing comprises preventing the adverse effect from the burst error by adjusting a chromatic dispersion compensation value of a tunable dispersion compensator and changing the frequency of the spectrum null of the optical signal received through the optical receiver.

15. The method of claim 13, wherein the preventing comprises preventing the adverse effect from the burst error by dispersing an optical signal output through an optical transmitter over time using an interleaver.

16. The method of claim 15, wherein activation of the interleaver is determined based on the burst error occurrence condition.
